(19) United States
(12) Patent Application Publication
(10) Pub. No.: US 2025/0022788 A1
(43) Pub. Date: Jan. 16, 2025

(54) SEMICONDUCTOR PACKAGE AND MANUFACTURING METHOD THEREOF

(71) Applicant: Samsung Electronics Co., Ltd., Suwon-si (KR)

(72) Inventors: KYOUNG LIM SUK, Suwon-si (KR); HYEONJEONG HWANG, Suwon-si (KR); Sehoon JANG, Suwon-si (KR)

(21) Appl. No.: 18/666,967

(22) Filed: May 17, 2024

(30) Foreign Application Priority Data
Jul. 11, 2023 (KR) 10-2023-0089895

(51) Int. Cl. H01L 23/498; H01L 21/48; H01L 21/768; H01L 23/00; H01L 23/528; H01L 25/10

(52) U.S. Cl. CPC H01L 23/49838; H01L 21/4857; H01L 21/76802; H01L 21/76877; H01L 23/49833; H01L 23/5286; H01L 25/105; H01L 24/08; H01L 24/16; H01L 2224/08225; H01L 2224/16225; H01L 2225/1023; H01L 2924/1815

(57) ABSTRACT

An embodiment provides a semiconductor package including: a first redistribution layer structure including a plurality of redistribution vias and a plurality of UBM structures; and a first semiconductor die on the first redistribution layer structure, wherein each of the plurality of UBM structures includes a UBM via; and a UBM wire line extending in a horizontal direction on the UBM via and electrically connecting one of the plurality of redistribution vias and the UBM via in the horizontal direction.

### CROSS-REFERENCE TO RELATED APPLICATION

This application claims priority and the benefit under 35 U.S.C. § 119to and of Korean Patent Application No. 10-2023-0089895, filed Jul. 11, 2023, in the Korean Intellectual Property Office, the entire contents of which are incorporated herein by reference.

### BACKGROUND OF THE INVENTION

### (a) Field of the Invention

The present disclosure relates to a semiconductor package and a manufacturing method thereof.

### (b) Description of the Related Art

Generally, solder or bumps may be used as a medium for connecting a semiconductor chip to a substrate and an interposer. However, since it may be difficult to directly connect the solder or bump on a conductive pad of the semiconductor chip, an under bump metallization (UBM) may be disposed between the conductive pad and the solder or bump to improve adhesion between the conductive pad and the solder or bump. However, even if the UBM is used as described above, adhesion between the UBM and a dielectric layer surrounding the UBM may not be well achieved, and thus a side surface of the UBM may be separated from the dielectric layer. To solve this problem, a T-type UBM technology capable of improving adhesion between the UBM and the dielectric layer by implementing the UBM in a T-shape and interposing an adhesion layer between the UBM and the dielectric layer has been developed.

However, when the T-type UBM technology is used, since one layer for forming an upper structure extending in a horizontal direction in a T-shape and another layer for forming an additional via structure for connecting the upper structure to a redistribution line are required, a turn around time (TAT) required for manufacturing a semiconductor package increases, and a cost for manufacturing the semiconductor package increases. In addition, since a thickness of a front side redistribution layer (FRDL) structure including the T-type UBM becomes thicker, in a package on package (POP) structure, a thickness difference occurs between the front side redistribution layer structure including the T-type UBM and a back side redistribution layer (BRDL) structure, and accordingly, warpage may occur in the semiconductor package when a room temperature or high temperature process is performed.

Therefore, it is necessary to develop a new semiconductor package technology that may solve the problems of the prior art.

### SUMMARY OF THE INVENTION

In the T-type under bump metallization (UBM) technology that may solve peeling of the side surface of the UBM, it is possible to provide a semiconductor package and a manufacturing method thereof in which an conventional upper structure, which has not functioned as a wire line, and an additional via structures for connecting the upper structure to a redistribution line are removed, and a wire line extending in the horizontal direction is formed in place of the upper structure.

An embodiment provides a semiconductor package including: a first redistribution layer structure including a plurality of redistribution vias and a plurality of UBM structures; and a first semiconductor die on the first redistribution layer structure, wherein each of the plurality of UBM structures includes a UBM via; and a UBM wire line extending in a horizontal direction on the UBM via and electrically connecting one of the plurality of redistribution vias and the UBM via in the horizontal direction.

Another embodiment provides a semiconductor package including: a first redistribution layer structure including a plurality of UBM structures, a plurality of redistribution vias, a plurality of redistribution lines on the plurality of UBM structures, and a dielectric layer, wherein the dielectric layer surrounds the plurality of UBM structures, the plurality of redistribution vias, and the plurality of redistribution lines; a plurality of connection members on a lower surface of the first redistribution layer structure; a first semiconductor die on the first redistribution layer structure; a plurality of conductive posts on the first redistribution layer structure; a molding material disposed on the first redistribution layer structure and molding the first semiconductor die and the plurality of conductive posts; a second redistribution layer structure on the molding material; and a second semiconductor die on the second redistribution layer structure, wherein each of the plurality of UBM structures includes a UBM via; and a UBM wire line extending in a horizontal direction on the UBM via and electrically connecting one of the plurality of redistribution vias and the UBM via in the horizontal direction.

Another embodiment provides a method of manufacturing a semiconductor package, including: forming a first redistribution layer structure including a plurality of UBM structures and a plurality of redistribution vias on a carrier, wherein each of the plurality of UBM structures includes a UBM via, and a UBM wire line extending in a horizontal direction on the UBM via and electrically connecting one of the plurality of redistribution vias and the UBM via in the horizontal direction; mounting a first semiconductor die on the first redistribution layer structure; forming a plurality of conductive posts on the first redistribution layer structure; molding the first semiconductor die and the plurality of conductive posts with a molding material on the first redistribution layer structure; and forming a second redistribution layer structure on the molding material.

In the T-type UBM technology including a lower structure extending in the vertical direction and an upper structure extending in the horizontal direction, the upper structure that has only a structural function to solve the separation of a side surface of the UBM from a dielectric but does not function as a wire is replaced with a wire line, and the redistribution via and the UBM via can be electrically connected in the horizontal direction by this wire line.

As a result, at least two layers may be removed from the front redistribution layer (FRDL) structure, thereby reducing the turn around time (TAT) required for manufacturing the semiconductor package and reducing the cost for manufacturing the semiconductor package.

In addition, since the thickness of the front redistribution layer (FRDL) structure is reduced, the difference in thickness between the front redistribution layer (FRDL) structure and the back redistribution layer (BRDL) structure is reduced, so when performing a room temperature or high temperature process, the warpage characteristic of the semiconductor package may be improved.

In addition, the movement path of signals and power in the front redistribution layer (FRDL) structure is shortened, wire resistance may be reduced, and power integrity (PI) characteristics may be improved.

### BRIEF DESCRIPTION OF THE DRAWINGS

FIG. 1 illustrates a cross-sectional view of a semiconductor package according to an example embodiment.

FIG. 2 illustrates an enlarged cross-sectional view of area A of the semiconductor package of FIG. 1.

FIG. 3 illustrates an enlarged cross-sectional view of area B of the semiconductor package of FIG. 1.

FIG. 4 illustrates enlarged cross-sectional views of areas C1 and C2 of the semiconductor package of FIG. 1.

FIG. 5 to FIG. 29 illustrate cross-sectional views of a manufacturing method of a semiconductor package according to an example embodiment.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

The drawings and description are to be regarded as illustrative in nature and not restrictive. Like reference numerals designate like elements throughout the specification and drawings.

Further, in the drawings, the size and thickness of each element are arbitrarily illustrated for ease of description, and the present disclosure is not necessarily limited to those illustrated in the drawings.

Throughout this specification and the claims that follow, when it is described that an element is “coupled or connected” to another element, the element may be “directly coupled or connected” to the other element or “indirectly coupled or connected” to the other element through a third element.

In addition, unless explicitly described to the contrary, the word “comprise” and variations such as “comprises” or “comprising” will be understood to imply the inclusion of stated elements but not the exclusion of any other elements.

It will be understood that when an element is referred to as being “connected” or “coupled” to or “on” another element, it can be directly connected or coupled to or on the other element or intervening elements may be present. In contrast, when an element is referred to as being “directly connected” or ‘directly coupled” to another element, or as “contacting” or “in contact with” another element (or using any form of the word “contact”), there are no intervening elements present at the point of contact.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Hereinafter, a semiconductor package 100 and a manufacturing method of the semiconductor package 100 according to an example embodiment will be described with reference to the accompanying drawings.

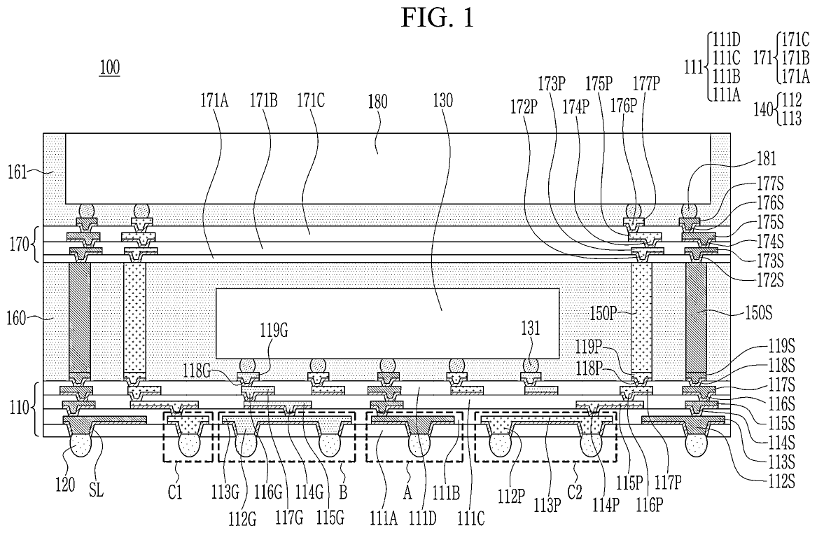

FIG. 1 illustrates a cross-sectional view of a semiconductor package 100 according to an example embodiment.

Referring to FIG. 1, the semiconductor package 100 may include a front side redistribution layer structure (first redistribution layer structure) 110, external connection members 120, a first semiconductor die 130, conductive posts 150, a first molding material 160, a back side redistribution layer structure (second redistribution layer structure) 170, a second semiconductor die 180, and a second molding material 161. In example embodiments, the semiconductor package 100 may include a package on package (POP). In example embodiments, the semiconductor package 100 may include a fan out wafer level package (FOWLP) or a fan out panel level package (FOPLP).

According to the present disclosure, S is added after a reference numeral of a configuration corresponding to a wire path that transmits a signal, P is added after a reference numeral of a configuration corresponding to a wire path that transmits power, and G is added after a reference numeral of a configuration corresponding to a wire path connected to the ground. In addition, in order to distinguish the wire path that transmits signals, the wire path that transmits power, and the wire path that is connected to the ground, a different pattern is displayed for each wire path. Therefore, even if no reference numeral is denoted, a configuration having the same pattern as the pattern of the configuration with S added after the reference numeral represents a wire path for transmitting a signal, a configuration having the same pattern as the pattern of the configuration with P appended after the reference numeral represents a wire path that transmits power, and a configuration having the same pattern as the pattern of the configuration with G added after the reference numeral represents a wire path connected to the ground.

The front side redistribution layer structure 110 may include a first dielectric layer 111, under bump metallization (UBM) structures 140, first redistribution vias 114 (e.g., first redistribution vias 114P, 114G, and 114S), first redistribution lines 115 (e.g., first redistribution lines 115P, 115G, and 115S), second redistribution vias 116 (e.g., second redistribution vias 116P, 116G, and 116S), second redistribution lines 117 (e.g., second redistribution lines 117P, 117G, and 117S), third redistribution vias 118 (e.g., third redistribution vias 118P, 118G, and 118S) in the first dielectric layer 111, and first bonding pads 119 (e.g., first bonding pads 119P, 119G, and 119S). The first semiconductor die 130 and the conductive posts 150 may be disposed on an upper surface of the front side redistribution layer structure 110. The external connection members 120 may be disposed on a lower surface of the front side redistribution layer structure 110.

The first dielectric layer 111 may protect and insulate the UBM structures 140, the first redistribution vias 114, the first redistribution lines 115, the second redistribution vias 116, the second redistribution lines 117, and the third redistribution vias 118. According to the present disclosure, it is illustrated that the first dielectric layer 111 is shown as first dielectric layers 111A to 111D having boundaries with each other from the bottom in the order of film-formation in the manufacturing process, but in the semiconductor package of the final product, the first dielectric layer 111A to the first dielectric layer 111D may be formed as an integral first dielectric layer 111 without being distinguished from each other.

The UBM structures 140 may include signal UBM structures 140S, ground UBM structures 140G, and power UBM structures 140P. The signal UBM structures 140S, the ground UBM structures 140G, and the power UBM structures 140P are disposed at positions spaced apart from each other, and may be electrically separated from each other.

Each UBM structure 140 may include a first area including a UBM via 112 and a second area including the UBM wire line 113. The first area and the second area may form an integral structure without a boundary. The UBM structure 140 may have a T-shape by combining the first area and the second area. The first area may correspond to a lower structure extending in a vertical direction in a T-shape. The second area may correspond to an upper structure extending in a horizontal direction in a T-shape. Based on the first area, the second area may have a first portion extending in one direction and in a horizontal direction, and a second portion extending in another direction opposite to the one direction and in the horizontal direction. In the embodiment, the first portion and the second portion may have lengths in different horizontal directions. In the embodiment, the first portion and the second portion may have lengths in the same horizontal direction.

The first area may be surrounded by the first dielectric layer 111A. The UBM vias 112 may be disposed between the UBM wire lines 113 and the external connection members 120. The UBM vias 112 may electrically connect the UBM wire lines 113 to the external connection members 120 in a vertical direction. A seed metal layer SL may be disposed between side surfaces of the UBM vias 112 and the first dielectric layer 111A. For example, the seed metal layer SL may contact the side surfaces of the UBM vias 112, and the first dielectric layer 111A may contact side surfaces of the seed metal layer SL.

The second area may be surrounded by the first dielectric layer 111B. The UBM wire line 113 may be disposed on the UBM via 112, and may extend in the horizontal direction. The UBM wire line 113 may be disposed between the UBM via 112 and the first redistribution via 114. The UBM wire line 113 may electrically connect the first redistribution via 114 to the UBM via 112 in the horizontal direction. The UBM wire line 113 may function as routing. A width of the UBM wire line 113 in the horizontal direction may be greater than that of the UBM via 112 in the horizontal direction. A seed metal layer SL may be disposed between a lower surface of the UBM wire line 113 and the first dielectric layer 111A. For example, the seed metal layer SL may contact lower surfaces of the UBM wire lines 113, and the first dielectric layer 111A may contact lower surfaces of the seed metal layer SL below the UBM wire lines 113. In addition, the first dielectric layer 111B may contact side surfaces of the UBM wire lines 113 and side surfaces of the seed metal layer SL below the UBM wire lines 113.

The UBM structure 140 according to the present disclosure includes the UBM via 112 corresponding to the lower structure extending in the vertical direction in the T-shape and the UBM wire line 113 corresponding to the upper structure extending in the horizontal direction in the T-shape, so that it may have a function in terms of structure to solve the peeling of the side surface of the UBM, and have a routing function by the UBM wire line 113 by forming the upper structure extending in the horizontal direction in the T-shape with the UBM wire line 113.

Thus, according to the present disclosure, at least two layers of a redistribution line that may be formed on the UBM structure because a conventional UBM structure having a T-shape does not have a routing function and a via connecting the UBM structure and the redistribution line may be removed from the front side redistribution layer structure, and accordingly, a movement path of signals and power in the front side redistribution layer structure is shortened, wire resistance may be reduced, and power integrity (PI) characteristics may be improved. In the embodiment, compared to a semiconductor package including the conventional T-shaped UBM structure, the movement path length of signals and power in the front side redistribution layer structure 110 of the semiconductor package according to the present disclosure may be reduced by about 2 μm to about 40 μm.

The first redistribution vias 114 may be surrounded by the first dielectric layer 111B. The first redistribution vias 114 may be disposed between the first redistribution lines 115 and the UBM wire lines 113. The first redistribution vias 114 may electrically connect the first redistribution lines 115 to the UBM wire lines 113 in the vertical direction. The seed metal layer SL may be disposed between the side surfaces of the first redistribution vias 114 and the first dielectric layer 111B and between the lower surfaces of the first redistribution vias 114 and the UBM wire lines 113. For example, the seed metal layer SL may contact side and lower surfaces of the first redistribution vias 114, and the first dielectric layer 111B may contact side surfaces of the seed metal layer SL.

The first redistribution lines 115 may be surrounded by the first dielectric layer 111C. The first redistribution lines 115 may be disposed between the second redistribution vias 116 and the first redistribution vias 114. The first redistribution lines 115 may electrically connect the second redistribution vias 116 to the first redistribution vias 114 in the horizontal direction. A seed metal layer SL may be disposed between the lower surfaces of the first redistribution lines 115 and the first dielectric layer 111B. For example, the seed metal layer SL may contact lower surfaces of the first redistribution lines 115, and the first dielectric layer 111B may contact lower surfaces of the seed metal layer SL below the first redistribution lines 115. In addition, the first dielectric layer 111C may contact side surfaces of the first redistribution lines 115 and side surfaces of the seed metal layer SL below the first redistribution lines 115.

The second redistribution vias 116 may be surrounded by the first dielectric layer 111C. The second redistribution vias 116 may be disposed between the second redistribution lines 117 and the first redistribution lines 115. The second redistribution vias 116 may electrically connect the second redistribution lines 117 to the first redistribution lines 115 in the vertical direction. A seed metal layer SL may be disposed between the side surfaces of the second redistribution vias 116 and the first dielectric layer 111C, and between the lower surfaces of the second redistribution vias 116 and the first redistribution lines 115. For example, the seed metal layer SL may contact side and lower surfaces of the second redistribution vias 116, and the first dielectric layer 111C may contact side surfaces of the seed metal layer SL.

The second redistribution lines 117 may be surrounded by the first dielectric layer 111D. The second redistribution lines 117 may be disposed between the third redistribution vias 118 and the second redistribution vias 116. The second redistribution lines 117 may electrically connect the third redistribution vias 118 to the second redistribution vias 116 in the horizontal direction. A seed metal layer SL may be disposed between the lower surfaces of the second redistribution lines 117 and a first dielectric layer 111C. For example, the seed metal layer SL may contact lower surfaces of the second redistribution lines 117, and the first dielectric layer 111C may contact lower surfaces of the seed metal layer SL below the second redistribution lines 117. In addition, the first dielectric layer 111D may contact side surfaces of the second redistribution lines 117 and side surfaces of the seed metal layer SL below the second redistribution lines 117.

The third redistribution vias 118 may be surrounded by the first dielectric layer 111D. The third redistribution vias 118 may be disposed between the first bonding pads 119 and the second redistribution lines 117. The third redistribution vias 118 may electrically connect the first bonding pads 119 to the second redistribution lines 117 in the vertical direction. A seed metal layer SL may be disposed between the side surfaces of the third redistribution vias 118 and the first dielectric layer 111D, and between the lower surfaces of the third redistribution vias 118 and the second redistribution lines 117. For example, the seed metal layer SL may contact side and lower surfaces of the third redistribution vias 118, and the first dielectric layer 111D may contact side surfaces of the seed metal layer SL.

The first bonding pads 119 may be surrounded by the first molding material 160. The first bonding pads 119 may be disposed between the conductive posts 150 and the third redistribution vias 118. The first bonding pads 119 may electrically connect the conductive posts 150 to the third redistribution vias 118 in the vertical direction. A seed metal layer SL may be disposed between the lower surfaces of the first bonding pads 119 and the first dielectric layer 111D. For example, the seed metal layer SL may contact lower surfaces of the first bonding pads 119, and the first dielectric layer 111D may contact lower surfaces of the seed metal layer SL below the first bonding pads 119. In addition, the first molding material 160 may contact side surfaces of the first bonding pads 119 and side surfaces of the seed metal layer SL below the first bonding pads 119.

The external connection members 120 may be disposed on the lower surface of the front side redistribution layer structure 110. The external connection member 120 may directly contact the UBM via 112, and may electrically connect the semiconductor package 100 to an external device.

In example embodiments, uppermost surfaces of the external connection members 120 may be at a higher vertical level than a lower surface of the first dielectric layer 111A. The seed metal layer SL formed on the side surfaces of the UBM vias 112 may contact the external connection members 120. For example, the seed metal layer SL formed on the side surfaces of the UBM vias 112 may contact a surface of each of the external connection members 120 that is recessed from the lower surface of the first dielectric layer 111A.

The first semiconductor die 130 may be disposed on the upper surface of the front side redistribution layer structure 110. In the embodiment, the first semiconductor die 130 may include a system on chip (SOC). In the embodiment, the first semiconductor die 130 may include integrated circuits including at least one of a memory circuit, a logic circuit, and the like. The first semiconductor die 130 may include connection members 131, and may be electrically connected to the first bonding pad 119 of the front side redistribution layer structure 110 through the connection members 131. For example, the connection members 131 may contact the first bonding pad 119 of the front side redistribution layer structure 110. In the embodiment, the connection member 131 may include micro bumps.

The conductive posts 150 may be disposed on the upper surface of the front side redistribution layer structure 110. The conductive posts 150 may be disposed between fourth redistribution vias 172 of the back side redistribution layer structure 170 and the first bonding pads 119. The conductive posts 150 may electrically connect the fourth redistribution vias 172 of the back side redistribution layer structure 170 to the first bonding pads 119. For example, each conductive post 150 may contact a lower surface of a seed metal layer SL below one of the fourth redistribution vias 172 and an upper surface of a corresponding one of the first bonding pads 119. The conductive posts 150 may be disposed through the first molding material 160. A side surface of each conductive post 150 may be surrounded by the first molding material 160. For example, the first molding material 160 may contact the side surfaces of the conductive posts 150. The conductive posts 150 may include signal conductive posts 150S, power conductive posts 150P, and ground conductive posts 150G (not shown).

The first molding material 160 may mold the first semiconductor die 130 and the conductive posts 150 on the front side redistribution layer structure 110. For example, the first molding material 160 may surround and contact the first semiconductor die 130, the conductive posts 150, and the front side redistribution layer structure 110. An upper surface of the first molding material 160 may be coplanar with upper surfaces of the conductive posts 150, and the upper surfaces of the first molding material 160 and the conductive posts 150 may be at a higher vertical level than an upper surface of the first semiconductor die 130. Side surfaces of the first molding material 160 may be aligned with side surfaces of the front side redistribution layer structure 110. The first molding material 160 protects the first semiconductor die 130 and the conductive posts 150 from an external environment, thereby ensuring electrical or mechanical stability of the semiconductor package 100.

The back side redistribution layer structure 170 may be disposed on the first molding material 160. The back side redistribution layer structure 170 may include a second dielectric layer 171, and fourth redistribution vias 172 (e.g., fourth redistribution vias 172P and 172S), third redistribution lines 173 (e.g., third redistribution lines 173P and 173S), fifth redistribution vias 174 (e.g., fifth redistribution vias 174P and 174S), fourth redistribution lines 175 (e.g., fourth redistribution lines 175P and 175S), sixth redistribution vias 176 (e.g., sixth redistribution vias 176P and 176S) in the second dielectric layer 171, and second bonding pads 177 (e.g., second bonding pads 177P and 177S). The second semiconductor die 180 may be disposed on the upper surface of the back side redistribution layer structure 170. The first molding material 160 and the conductive posts 150 may be disposed on the lower surface of the back side redistribution layer structure 170.

The second dielectric layer 171 may protect and insulate the fourth redistribution vias 172, the third redistribution lines 173, the fifth redistribution vias 174, the fourth redistribution lines 175, and the sixth redistribution vias 176. According to the present disclosure, it is illustrated that the second dielectric layer 171 is shown as second dielectric layers 171A to 171C having boundaries with each other from the bottom in the order of film-formation in the manufacturing process, but in the semiconductor package of the final product, the second dielectric layer 171A to the second dielectric layer 171C may be formed as an integral second dielectric layer 171 without being distinguished from each other.

The fourth redistribution vias 172 may be surrounded by the second dielectric layer 171A. The fourth redistribution vias 172 may be disposed between the third redistribution lines 173 and the conductive posts 150. The fourth redistribution vias 172 may electrically connect the third redistribution lines 173 to the conductive posts 150 in the vertical direction. The seed metal layer SL may be disposed between the side surfaces of the fourth redistribution vias 172 and the second dielectric layer 171A, and between the lower surfaces of the fourth redistribution vias 172 and the conductive posts 150. For example, the seed metal layer SL may contact side and lower surfaces of the fourth redistribution vias 172, and the second dielectric layer 171A may contact side surfaces of the seed metal layer SL. A corresponding one of the conductive posts 150 may contact a lower surface of the seed metal layer SL below the fourth redistribution vias 172.

The third redistribution lines 173 may be surrounded by the second dielectric layer 171B. The third redistribution lines 173 may be disposed between the fifth redistribution vias 174 and the fourth redistribution vias 172. The third redistribution lines 173 may electrically connect the fifth redistribution vias 174 to the fourth redistribution vias 172 in the horizontal direction. The seed metal layer SL may be disposed between the lower surfaces of the third redistribution lines 173 and the second dielectric layer 171A. For example, the seed metal layer SL may contact a lower surface of the third redistribution lines 173, and the second dielectric layer 171A may contact a lower surface of the seed metal layer SL below the third redistribution lines 173. In addition, the second dielectric layer 171B may contact side surfaces of the third redistribution lines 173 and side surfaces of the seed metal layer SL below the third redistribution lines 173.

The fifth redistribution vias 174 may be surrounded by the second dielectric layer 171B. The fifth redistribution vias 174 may be disposed between the fourth redistribution lines 175 and the third redistribution lines 173. The fifth redistribution vias 174 may electrically connect the fourth redistribution lines 175 to the third redistribution lines 173 in the vertical direction. The seed metal layer SL may be disposed between the side surfaces of the fifth redistribution vias 174 and the second dielectric layer 171B, and between the lower surfaces of the fifth redistribution vias 174 and the third redistribution lines 173. For example, the seed metal layer SL may contact side and lower surfaces of the fifth redistribution vias 174, and the second dielectric layer 171B may contact side surfaces of the seed metal layer SL.

The fourth redistribution lines 175 may be surrounded by the second dielectric layer 171C. The fourth redistribution lines 175 may be disposed between the sixth redistribution vias 176 and the fifth redistribution vias 174. The fourth redistribution lines 175 may electrically connect the sixth redistribution vias 176 to the fifth redistribution vias 174 in the horizontal direction. The seed metal layer SL may be disposed between the lower surfaces of the fourth redistribution lines 175 and the second dielectric layer 171B. For example, the seed metal layer SL may contact lower surfaces of the fourth redistribution lines 175, and the second dielectric layer 171B may contact lower surfaces of the seed metal layer SL below the fourth redistribution lines 175. In addition, the second dielectric layer 171C may contact side surfaces of the fourth redistribution lines 175 and side surfaces of the seed metal layer SL below the fourth redistribution lines 175.

The sixth redistribution vias 176 may be surrounded by the second dielectric layer 171C. The sixth redistribution vias 176 may be disposed between the second bonding pads 177 and the fourth redistribution lines 175. The sixth redistribution vias 176 may electrically connect the second bonding pads 177 to the fourth redistribution lines 175 in the vertical direction. The seed metal layer SL may be disposed between the side surfaces of the sixth redistribution vias 176 and the second dielectric layer 171C, and between the lower surfaces of the sixth redistribution vias 176 and the fourth redistribution lines 175. For example, the seed metal layer SL may contact side and lower surfaces of the sixth redistribution vias 176, and the second dielectric layer 171C may contact side surfaces of the seed metal layer SL.

The second bonding pads 177 may be surrounded by the second molding material 161. The second bonding pads 177 may be disposed between connection members 181 of the second semiconductor die 180 and the sixth redistribution vias 176. The second bonding pads 177 may electrically connect the connection members 181 to the sixth redistribution vias 176 in the vertical direction. The seed metal layer SL may be disposed between the lower surfaces of the second bonding pads 177 and the second dielectric layer 171C.

For example, the seed metal layer SL may contact lower surfaces of the second bonding pads 177, and the second dielectric layer 171C may contact lower surfaces of the seed metal layer SL below the second bonding pads 177. In addition, the second molding material 161 may contact side surfaces of the second bonding pads 177 and side surfaces of the seed metal layer SL below the second bonding pads 177.

The second semiconductor die 180 may be disposed on the back side redistribution layer structure 170. In the embodiment, the second semiconductor die 180 may include a single chip such as a DRAM or a multiple chip such as a high bandwidth memory (HBM). In the embodiment, the second semiconductor die 180 may include integrated circuits including at least one of a memory circuit, a logic circuit, and the like. The second semiconductor die 180 may include the connection members 181, and may be electrically connected to the second bonding pad 177 of the back side redistribution layer structure 170 through the connection members 181. In the embodiment, the connection member 181 may include micro bumps.

The second molding material 161 may mold the second semiconductor die 180 on the back side redistribution layer structure 170. For example, the second molding material 161 may surround and contact the second semiconductor die 180. An upper surface of the second molding material 161 may be coplanar with an upper surface of the second semiconductor die 180. Side surfaces of the second molding material 161 may be aligned with side surfaces of the back side redistribution layer structure 170. The second molding material 161 protects the second semiconductor die 180 from an external environment, thereby ensuring electrical or mechanical stability of the semiconductor package 100.

In the example embodiment of FIG. 1, each of the UBM vias 112 (e.g., the UBM vias 112P, 112G, and 112S), the first redistribution vias 114 (e.g., the first redistribution vias 114P, 114G, and 114S), the second redistribution vias 116 (e.g., the second redistribution vias 116P, 116G, and 116S), the third redistribution vias 118 (e.g., the third redistribution vias 118P, 118G, and 118S), the fourth redistribution vias 172 (e.g., the fourth redistribution vias 172P and 172S), the fifth redistribution vias 174 (e.g., the fifth redistribution vias 174P and 174S), and the sixth redistribution vias 176 (e.g., the sixth redistribution vias 176P and 176S) may have a tapered shape. For example, a width of each of the UBM vias 112, the first redistribution vias 114, the second redistribution vias 116, the third redistribution vias 118, the fourth redistribution vias 172, the fifth redistribution vias 174, and the sixth redistribution vias 176 may be wider at an upper portion thereof, and narrower at a lower portion thereof.

According to the present disclosure, at least two layers of a redistribution line that may be formed on an upper portion of the UBM structure because the conventional T-shaped UBM structure does not have a routing function and a via connecting the UBM structure and the redistribution line, may be removed from the front side redistribution layer structure. Accordingly, since the thickness of the front side redistribution layer structure is reduced, the difference in thickness between the front side redistribution layer structure and the back side redistribution layer structure is reduced, so when performing a room temperature or high temperature process, the warpage characteristic of the semiconductor package of the package may be improved. In the semiconductor package including the conventional T-shaped UBM structure, the thickness ratio of the front side redistribution layer structure 110 and the back side redistribution layer structure 170 in the vertical direction is about 9:5, while in the semiconductor package 100 according to the present disclosure, the thickness ratio of the front side redistribution layer structure 110 and the back side redistribution layer structure 170 in the vertical direction is about 7:5, so a thickness balance between the upper structure and the lower structure of the semiconductor package 100 may be improved. In the embodiment, the thickness of the front side redistribution layer structure 110 in the vertical direction may be about 30 μm to about 40 μm.

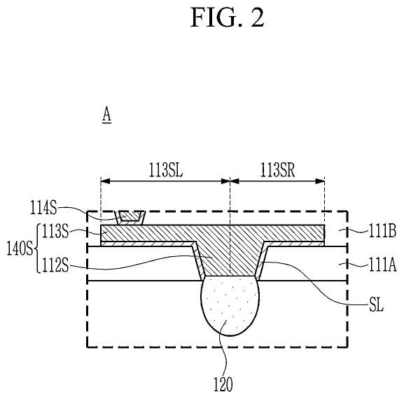

FIG. 2 illustrates an enlarged cross-sectional view of area A of the semiconductor package 100 of FIG. 1.

Referring to FIG. 2, the area A represents the signal UBM structure 140S of the UBM structure 140. The signal UBM structure 140S may include a signal UBM via 112S and a signal UBM wire line 113S. The signal UBM structure 140S may include one signal UBM via 112S and one signal UBM wire line 113S corresponding thereto. The signal UBM via 112S and the signal UBM wire line 113S may form an integral structure without a boundary. The signal UBM structure 140S may have a T-shape by combining the signal UBM via 112S and the signal UBM wire line 113S. The signal UBM via 112S may correspond to a lower structure extending in a vertical direction in the T-shape. The signal UBM wire line 113S may correspond to an upper structure extending in a horizontal direction in the T-shape.

The signal UBM wire line 113S may include a first portion 113SL extending in one direction and in the horizontal direction based on the signal UBM via 112S, and a second portion 113SR extending in another direction opposite to the one direction and in the horizontal direction. In the embodiment, a length of the first portion 113SL in the horizontal direction and a length of the second portion 113SR in the horizontal direction may be different. In the embodiment, the first portion 113SL and the second portion 113SR may have the same length in the horizontal direction.

The signal UBM via 112S may be surrounded by the first dielectric layer 111A. The signal UBM via 112S may be disposed between the signal UBM wire line 113S and the external connection member 120. The signal UBM via 112S may electrically connect the signal UBM wire line 113S to the external connection member 120 in the vertical direction. The seed metal layer SL may be disposed between the side surface of the signal UBM via 112S and the first dielectric layer 111A.

The signal UBM wire line 113S may be surrounded by the first dielectric layer 111B. The signal UBM wire line 113S may be disposed on the signal UBM via 112S, and may extend in the horizontal direction. The signal UBM wire line 113S may be disposed between the signal UBM via 112S and the first signal redistribution via 114S. The signal UBM wire line 113S may electrically connect the first signal redistribution via 114S to the signal UBM via 112S in the horizontal direction. The signal UBM wire line 113S may function as routing. A horizontal width of the signal UBM wire line 113S may be greater than that of the signal UBM via 112S. In order to perform a routing function, the signal UBM wire line 113S may have a length twice or more in the horizontal direction of the maximum width of the signal UBM via 112S in the horizontal direction. The seed metal layer SL may be disposed between the lower surface of the signal UBM wire line 113S and the first dielectric layer 111A. In the embodiment, the signal UBM wire line 113S may have an elongated shape in the horizontal direction, but is not limited thereto.

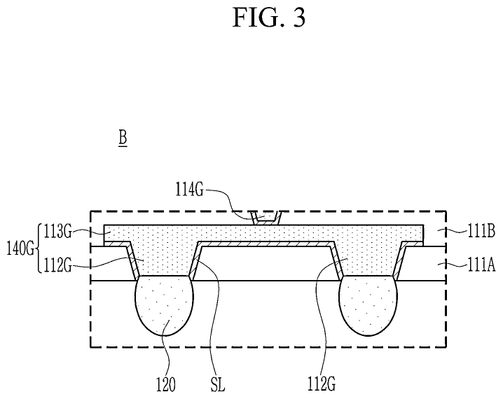

FIG. 3 illustrates an enlarged cross-sectional view of area B of the semiconductor package 100 of FIG. 1.

Referring to FIG. 3, the area B includes the ground UBM structure 140G of the UBM structure 140. The ground UBM structure 140G may include a ground UBM via 112G and a ground UBM wire line 113G. The ground UBM structure 140G may include one or more ground UBM vias 112G and one ground UBM wire line 113G corresponding thereto. The ground UBM via 112G and the ground UBM wire line 113G may form an integral structure without a boundary. In the embodiment, the ground UBM structure 140G may have a structure in which a plurality of ground UBM vias 112G and the ground UBM wire line 113G are combined. One ground UBM wire line 113G may merge a plurality of ground UBM vias 112G. A plurality of ground UBM vias 112G may correspond to a lower structure extending in the vertical direction. The ground UBM wire line 113G may correspond to an upper structure extending in the horizontal direction.

The ground UBM via 112G may be surrounded by the first dielectric layer 111A. The ground UBM via 112G may be disposed between the ground UBM wire line 113G and the external connection member 120. The ground UBM via 112G may electrically connect the ground UBM wire line 113G to the external connection member 120 in the vertical direction. The seed metal layer SL may be disposed between the side surface of the ground UBM via 112G and the first dielectric layer 111A.

The ground UBM wire line 113G may be surrounded by the first dielectric layer 111B. The ground UBM wire line 113G may be disposed on the ground UBM via 112G, and may extend in the horizontal direction. The ground UBM wire line 113G may be disposed between the ground UBM via 112G and the first ground redistribution via 114G. The ground UBM wire line 113G may electrically connect the first ground redistribution via 114G to the ground UBM via 112G in the horizontal direction. The ground UBM wire line 113G may function as routing. The horizontal width of the ground UBM wire line 113G may be greater than that of the ground UBM via 112G. In order to perform a routing function, the ground UBM wire line 113G may have a length twice or more in the horizontal direction of the maximum width of the ground UBM via 112G in the horizontal direction. The seed metal layer SL may be disposed between the lower surface of the ground UBM wire line 113G and the first dielectric layer 111A. In the embodiment, the ground UBM wire line 113G may have a plate-like shape in a plan view, but is not limited thereto.

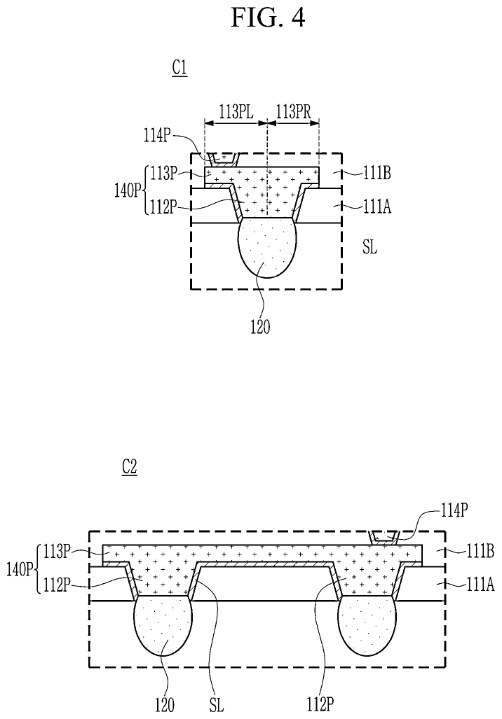

FIG. 4 illustrates enlarged cross-sectional views of areas C1 and C2 of the semiconductor package 100 of FIG. 1.

Referring to FIG. 4, the areas C1 and C2 include the power UBM structure 140P of the UBM structure 140. In the area C1, the power UBM structure 140P may include a power UBM via 112P and a power UBM wire line 113P. The power UBM structure 140P may include one power UBM via 112P and one power UBM wire line 113P corresponding thereto. The power UBM via 112P and the power UBM wire line 113P may form an integral structure without a boundary. The power UBM structure 140P may have a T-shape by combining the power UBM via 112P and the power UBM wire line 113P. The power UBM via 112P may correspond to a lower structure extending in the vertical direction in the T-shape. The power UBM wire line 113P may correspond to an upper structure extending in the horizontal direction in the T shape.

In the area C1, the power UBM wire line 113P may include a first portion 113PL extending in one direction and in the horizontal direction, and a second portion 113PR extending in the other direction opposite to one direction and in the horizontal direction, based on the power UBM via 112P. In the embodiment, a length of the first portion 113PL in the horizontal direction and a length of the second portion 113PR in the horizontal direction may be different. In the embodiment, the first portion 113PL and the second portion 113PR may have the same length in the horizontal direction.

In the area C2, the power UBM structure 140P may include one or more power UBM vias 112P and one power UBM wire line 113P corresponding thereto, and the power UBM via 112P and the power UBM wire line 113P may form an integral structure without a boundary. In the embodiment, the power UBM structure 140P may have a structure in which a plurality of power UBM vias 112P and the power UBM wire line 113P are combined. One power UBM wire line 113P may merge a plurality of power UBM vias 112P. A plurality of power UBM vias 112P may correspond to a lower structure extending in the vertical direction. The power UBM wire line 113P may correspond to an upper structure extending in the horizontal direction.

In the areas C1 and C2, the power UBM vias 112P may be surrounded by the first dielectric layer 111A. The power UBM vias 112P may be disposed between the power UBM wire lines 113P and the external connection members 120. The power UBM vias 112P may electrically connect the power UBM wire lines 113P to the external connection members 120 in the vertical direction. The seed metal layer SL may be disposed between the side surface of the power UBM vias 112P and the first dielectric layer 111A.

In the areas C1 and C2, the power UBM wire lines 113P may be surrounded by the first dielectric layer 111B. The power UBM wire lines 113P may be disposed on the power UBM vias 112P, and may extend in the horizontal direction. The power UBM wire lines 113P may be disposed between the power UBM vias 112P and the first power redistribution vias 114P. The power UBM wire lines 113P may electrically connect the first power redistribution vias 114P to the power UBM vias 112P in the horizontal direction. The power UBM wire lines 113P may function as routing. A horizontal direction width of the power UBM wire lines 113P may be greater than that of the power UBM vias 112P. In order to perform a routing function, the power UBM wire lines 113P may have a length twice or more in the horizontal direction of the maximum width of the power UBM vias 112P in the horizontal direction. The seed metal layer SL may be disposed between the lower surface of the power UBM wire lines 113P and the first dielectric layer 111A.

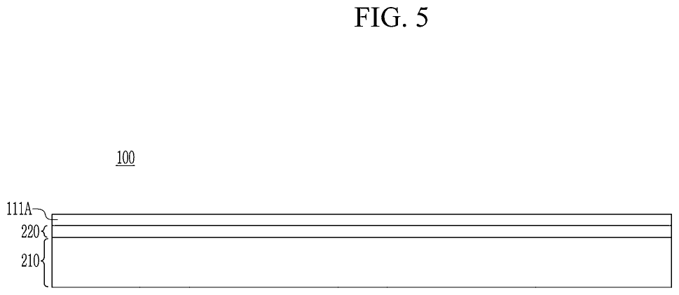

FIG. 5 to FIG. 29 illustrate cross-sectional views of a manufacturing method of the semiconductor package 100 according to an example embodiment.

FIG. 5 illustrates a cross-sectional view of a step of film-forming the first dielectric layer 111A on a carrier 210.

Referring to FIG. 5, the carrier 210 may be provided. The carrier 210 may be formed of or include, for example, a silicon-based material such as glass or a silicon oxide, an organic material, or another material such as an aluminum oxide, a combination of these materials, and the like.

A release layer 220 may be disposed on the carrier 210. The release layer may be configured as a multilayer, and may include, for example, an adhesive layer and a release layer. The release layer 220 may be removed along with the carrier 210 from the front side redistribution layer structure 110 after subsequent processing. An upper surface of the release layer 220 may be flat and have a high degree of coplanarity. In the embodiment, the release layer 220 may be formed of or include a polymer-based material. In the embodiment, the release layer 220 may include a light-to-heat-conversion (LTHC) release coating material, and may be thermally-released by heating. In the embodiment, the release layer 220 may include an ultra-violet (UV) adhesive that is released by UV light. In the embodiment, the release layer 220 may be released by a physical method. In the embodiment, the release layer 220 may be applied in a liquid or cured state. In the embodiment, the release layer 220 may be a laminate film laminated on the carrier 210.

The first dielectric layer 111A may be formed on the carrier 210. In the embodiment, the first dielectric layer 111 may include a photoimageable dielectric (PID) used in a redistribution process. The photoimageable dielectric is a material in which fine patterns may be formed by applying a photolithography process. As an example, the PID may be formed of or include a polyimide-based photosensitive polymer, a novolak-based photosensitive polymer, polybenzoxazole, a silicon-based polymer, an acrylate-based polymer, or an epoxy-based polymer. In the embodiment, the first dielectric layer 111 is made of an inorganic dielectric material such as a silicon nitride, a silicon oxide, or the like. In the embodiment, the first dielectric layer 111 may be formed by a CVD, ALD, or PECVD process.

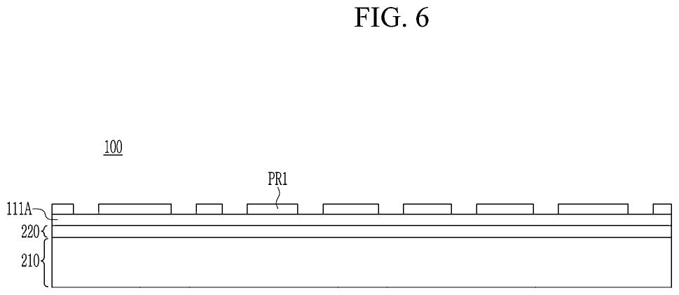

FIG. 6 illustrates a cross-sectional view of a step of forming a photoresist pattern PR1 on the first dielectric layer 111A.

Referring to FIG. 6, a photoresist may be formed on the first dielectric layer 111A. In the embodiment, the photoresist may be formed through spin coating. In the embodiment, the photoresist may include an organic polymeric resin containing a photoactive material. In another embodiment, the photoresist may include an inorganic material. In another embodiment, the photoresist may be formed through a sputtering process, a physical vapor deposition (PVD) process, an atomic layer deposition (ALD) process, or a chemical vapor deposition (CVD) process. Thereafter, the photoresist may be exposed and developed to form a pattern on the photoresist to form the photoresist pattern PR1.

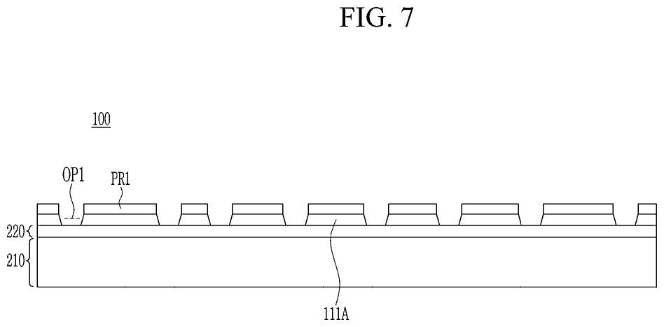

FIG. 7 illustrates a cross-sectional view of a step of etching a portion of the first dielectric layer 111A.

Referring to FIG. 7, the first dielectric layer 111A may be etched using the photoresist pattern PR1 as an etching mask, and first openings OP1 may be formed in the first dielectric layer 111A. An upper surface of the carrier 210 or release layer 220 may be exposed through the first openings OP1 formed in the first dielectric layer 111A. The first openings OP1 may have a shape in which widths of the first openings OP1 decrease in a direction from an upper surface of the first dielectric layer 111A to a lower surface of the first dielectric layer 111A.

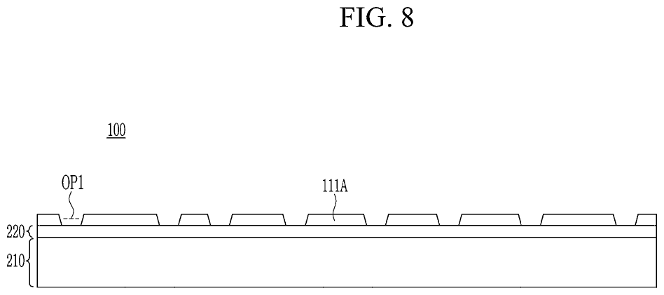

FIG. 8 illustrates a cross-sectional view of a step of removing the photoresist pattern PR1.

Referring to FIG. 8, the photoresist pattern PR1 on the first dielectric layer 111A may be removed. In the embodiment, the photoresist pattern PR1 may be removed by performing at least one of an ashing process and a strip process.

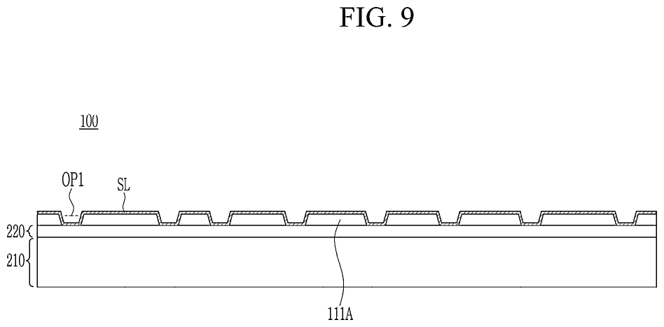

FIG. 9 illustrates a cross-sectional view of a step of film-forming the seed metal layer SL.

Referring to FIG. 9, the seed metal layer SL may be formed conformally on the upper surface of the carrier 210 or the release layer 220, the inner walls of the first openings OP1 of the first dielectric layer 111A, and the upper surface of the first dielectric layer 111A. In the embodiment, the seed metal layer SL may include copper. In the embodiment, the seed metal layer SL may include a conductive material capable of electrolytic plating. The seed metal layer SL may include an adhesion layer. The adhesion layer may improve adherence between the first dielectric layer 111A and the UBM structure 140, thereby preventing separation (or release) of the UBM structure 140 from the first dielectric layer 111A. In the embodiment, the adhesion layer may include at least one of titanium, titanium nitride, and copper. In the embodiment, the seed metal layer SL may be formed by electroless plating. In the embodiment, a cleaning process or a metal catalyst activation pretreatment process may be performed prior to the electroless plating. In another embodiment, the seed metal layer SL may be formed by sputtering.

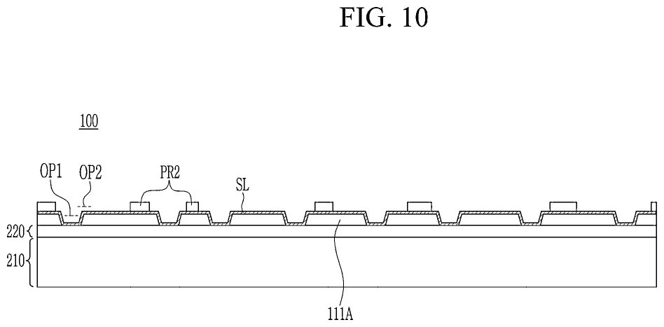

FIG. 10 illustrates a cross-sectional view of a step of forming a photoresist pattern PR2 on the seed metal layer SL.

Referring to FIG. 10, a photoresist may be formed on the first dielectric layer SL. In the embodiment, the photoresist may be formed through spin coating. In the embodiment, the photoresist may include an organic polymeric resin containing a photoactive material. In another embodiment, the photoresist may include an inorganic material. In another embodiment, the photoresist may be formed through a sputtering process, a physical vapor deposition (PVD) process, an atomic layer deposition (ALD) process, or a chemical vapor deposition (CVD) process. Thereafter, the photoresist may be exposed and developed to form a pattern on the photoresist to form the photoresist pattern PR2. The photoresist pattern PR2 may include second openings OP2. A portion of the upper surface of the seed metal layer SL and the first openings OP1 may be exposed in the second openings OP2 of the photoresist pattern PR2.

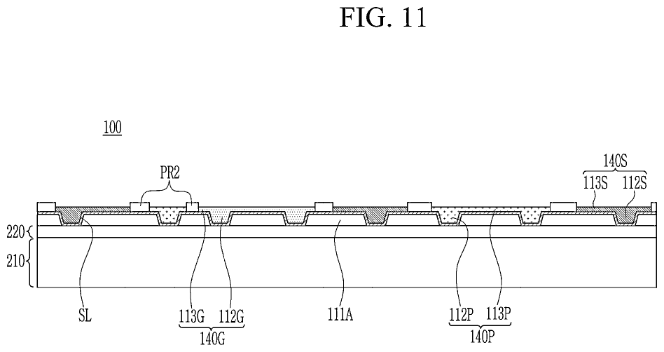

FIG. 11 illustrates a cross-sectional view of a step of forming the UBM structure 140 in the first openings OP1 of the first dielectric layer 111A and the second openings OP2 of the photoresist pattern PR2.

Referring to FIG. 11, the UBM structures 140 may be formed in the first openings OP1 of the first dielectric layer 111A and the second openings OP2 of the photoresist pattern PR2. The UBM via 112 and UBM wire line 113 of each of the UBM structures 140 may be integrally formed by a single film-formation process. In the embodiment, the UBM structures 140 may include copper. In another embodiment, the UBM structures 140 may include a conductive material capable of electrolytic plating. In the embodiment, the UBM structures 140 may be formed by electrolytic plating. The UBM structures 140 may be formed by growing a metal layer by electrolytic plating from the previously formed seed metal layer SL. During the electroplating process, the electrolytic plating may be finished before the UBM structures 140 are film-formed over the upper surface of the photoresist pattern PR2. In this case, a separate chemical mechanical polishing (CMP) process may not be performed.

In the embodiment, an annealing process may be performed after the UBM structures 140 are formed.

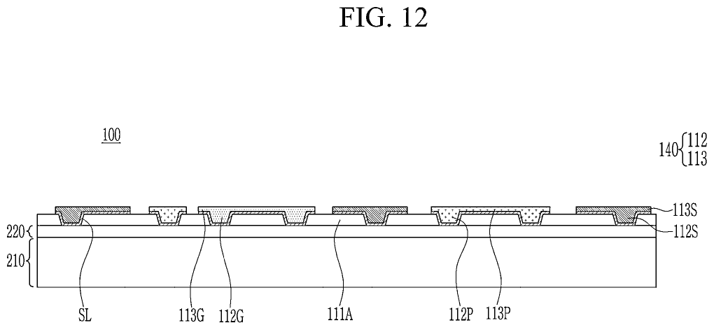

FIG. 12 illustrates a cross-sectional view of a step of removing the photoresist pattern PR2.

Referring to FIG. 12, the photoresist pattern PR2 on the seed metal layer SL may be removed. In the embodiment, the photoresist pattern PR2 may be removed by performing at least one of an ashing process and a strip process.

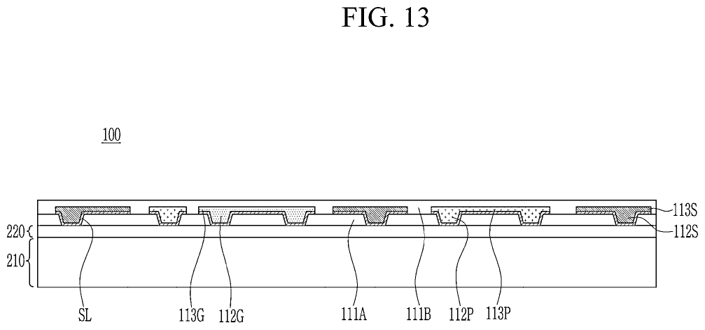

FIG. 13 illustrates a cross-sectional view of a step of film-forming the first dielectric layer 111B on the first dielectric layer 111A and the UBM structures 140.

Referring to FIG. 13, the first dielectric layer 111B may be film-formed on the first dielectric layer 111A and the UBM structures 140. The first dielectric layer 111B may be formed to cover the UBM structures 140. For example, the first dielectric layer 111B may contact upper surfaces of the UBM structures 140.

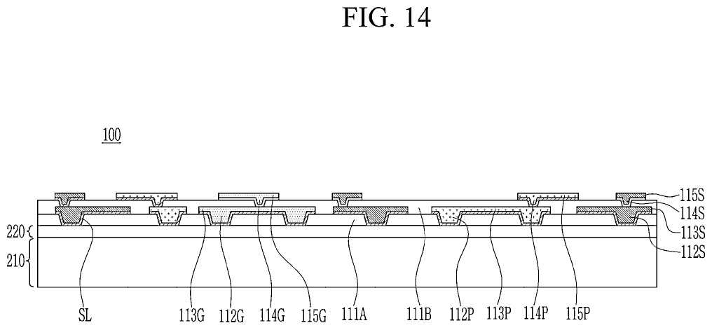

FIG. 14 illustrates a cross-sectional view of a step of forming the first redistribution vias 114 and the first redistribution lines 115 on the UBM structures 140.

Referring to FIG. 14, the first redistribution vias 114 and the first redistribution lines 115 may be formed on the UBM structures 140. The contents described with reference to FIG. 6 to FIG. 12 in which the steps of forming the UBM structures 140 are described and illustrated may be equally applied to the steps of forming the first redistribution vias 114 and the first redistribution lines 115. In the embodiment, the first redistribution vias 114 and the first redistribution lines 115 may include at least one of copper, aluminum, tungsten, nickel, gold, tin, titanium, and an alloy thereof.

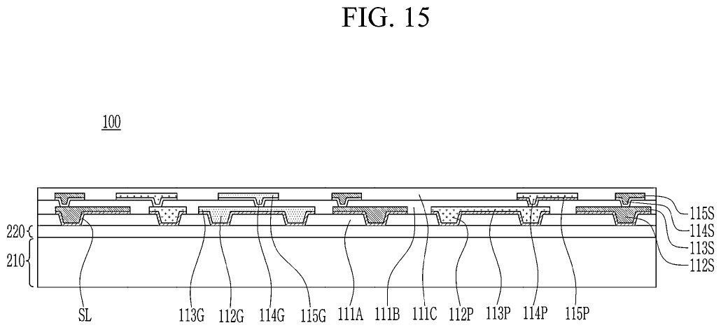

FIG. 15 illustrates a cross-sectional view of a step of film-forming the first dielectric layer 111C on the first dielectric layer 111B and the first redistribution lines 115.

Referring to FIG. 15, the first dielectric layer 111C may be film-formed on the first dielectric layer 111B and the first redistribution lines 115. The first dielectric layer 111C may be formed to cover the first redistribution lines 115. The first dielectric layer 111C may contact upper surfaces of the first redistribution lines 115.

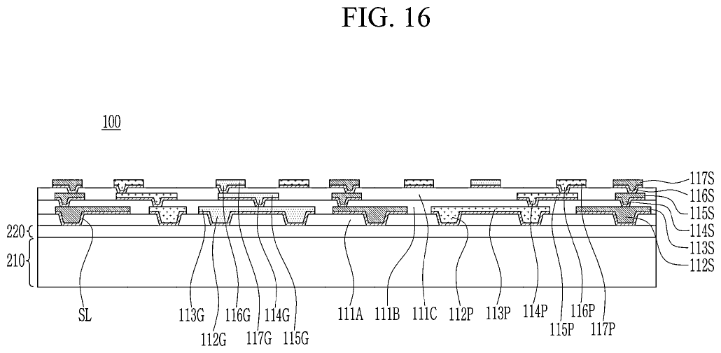

FIG. 16 illustrates a cross-sectional view of a step of forming the second redistribution vias 116 and the second redistribution lines 117 on the first redistribution lines 115.

Referring to FIG. 16, the second redistribution vias 116 and the second redistribution lines 117 may be formed on the first redistribution lines 115. The contents described with reference to FIG. 6 to FIG. 12 in which the steps of forming the UBM structures 140 are described and illustrated may be equally applied to the steps of forming the second redistribution vias 116 and the second redistribution lines 117. In the embodiment, the second redistribution vias 116 and the second redistribution lines 117 may include at least one of copper, aluminum, tungsten, nickel, gold, tin, titanium, and an alloy thereof.

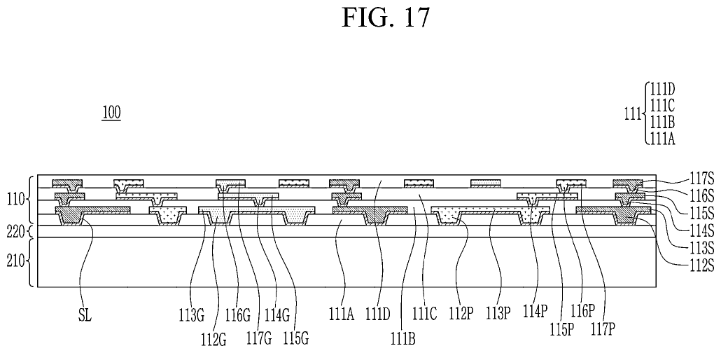

FIG. 17 illustrates a cross-sectional view of a step of film-forming the first dielectric layer 111D on the first dielectric layer 111C and the second redistribution lines 117.

Referring to FIG. 17, the first dielectric layer 111D may be film-formed on the first dielectric layer 111C and the second redistribution lines 117. The first dielectric layer 111D may be formed to cover the second redistribution lines 117. The first dielectric layer 111D may contact upper surfaces of the second redistribution lines 117.

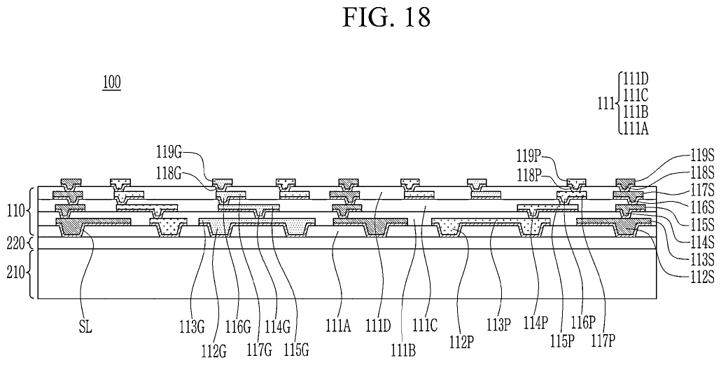

FIG. 18 illustrates a cross-sectional view of a step of forming the third redistribution vias 118 and the first bonding pads 119 on the second redistribution line 117.

Referring to FIG. 18, the third redistribution vias 118 and the first bonding pads 119 may be formed on the second redistribution line 117. The contents described with reference to FIG. 6 to FIG. 12 in which the steps of forming the UBM structures 140 are described and illustrated may be equally applied to the steps of forming the third redistribution vias 118 and the first bonding pads 119. In the embodiment, the third redistribution vias 118 and the first bonding pads 119 may include at least one of copper, aluminum, tungsten, nickel, gold, tin, titanium, and an alloy thereof.

As described above, according to the present disclosure, at least two layers of a redistribution line formed on the UBM structure 140 and a via connecting the UBM structure 140 and the redistribution line may be removed from the front side redistribution layer structure, whereby a turn around time (TAT) required for manufacturing the semiconductor package may be reduced, and a cost for manufacturing the semiconductor package may be reduced.

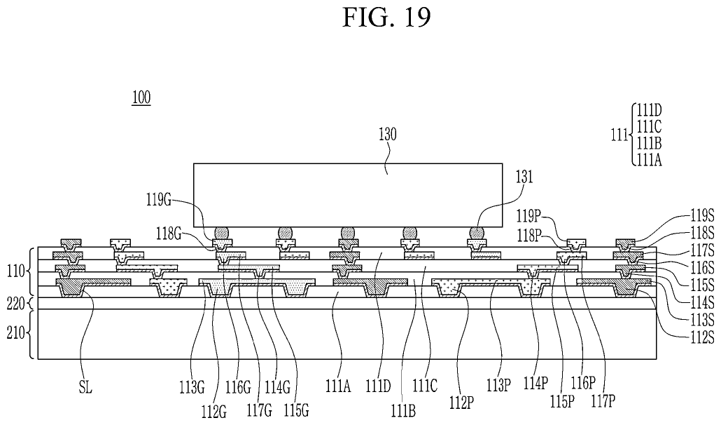

FIG. 19 illustrates a cross-sectional view of a step of mounting the first semiconductor die 130 on the front side redistribution layer structure 110.

Referring to FIG. 19, the first semiconductor die 130 may be mounted on the front side redistribution layer structure 110. The connection members 131 of the first semiconductor die 130 may be bonded to the first bonding pads 119 of the front side redistribution layer structure 110 so that the first semiconductor die 130 and the front side redistribution layer structure 110 may be electrically connected.

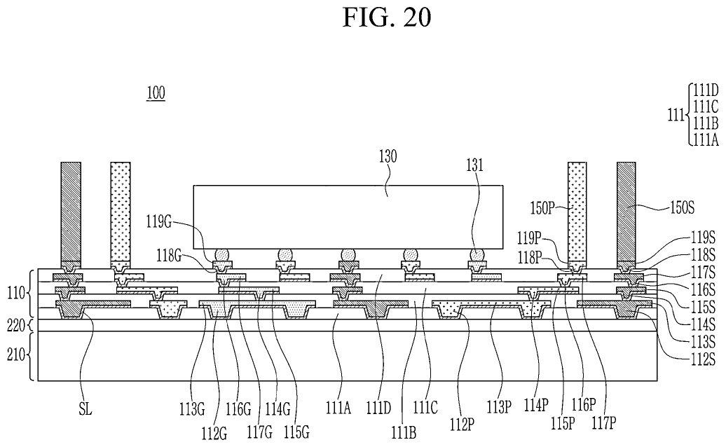

FIG. 20 illustrates a cross-sectional view of a step of forming conductive posts 150 on the front side redistribution layer structure 110.

Referring to FIG. 20, the conductive posts 150 may be bonded onto the front side redistribution layer structure 110 and formed in the vertical direction. In the embodiment, the conductive posts 150 may be formed by performing a sputtering process. In another embodiment, the conductive posts 150 may be formed by performing an electrolytic plating process after forming the seed metal layer. In the embodiment, the conductive posts 150 may include at least one of copper, aluminum, tungsten, nickel, gold, silver, chromium, antimony, tin, titanium, and an alloy thereof.

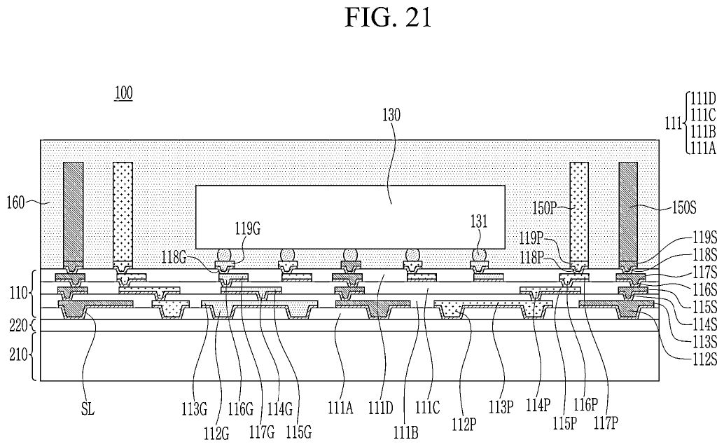

FIG. 21 illustrates a cross-sectional view of a step of molding the first semiconductor die 130 and the conductive posts 150 on the front side redistribution layer structure 110.

Referring to FIG. 21, the first semiconductor die 130 and the conductive posts 150 may be molded on the front side redistribution layer structure 110 by the first molding material 160. In the embodiment, the process of molding with the first molding material 160 may include a compression molding or transfer molding process. In the embodiment, the first molding material 160 may include an epoxy molding compound (EMC).

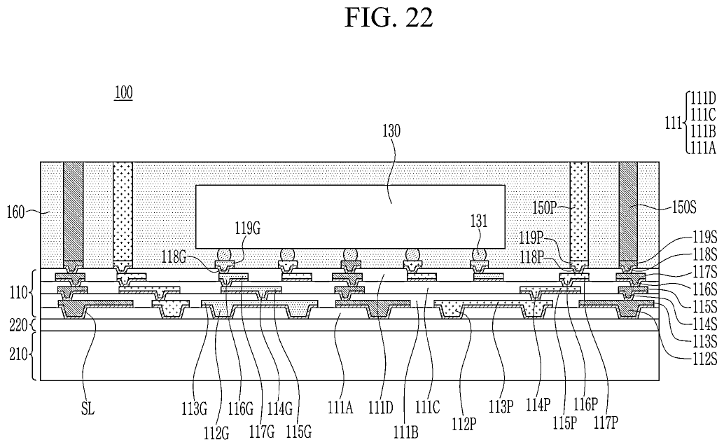

FIG. 22 illustrates a cross-sectional view of a step of performing a chemical mechanical polishing (CMP) process on the first molding material 160.

Referring to FIG. 22, the upper surface of the first molding material 160 may be planarized by performing a chemical mechanical polishing (CMP) process so as to level the upper surface of the first molding material 160. After performing the chemical mechanical polishing (CMP) process, upper surfaces of the conductive posts 150 may be exposed.

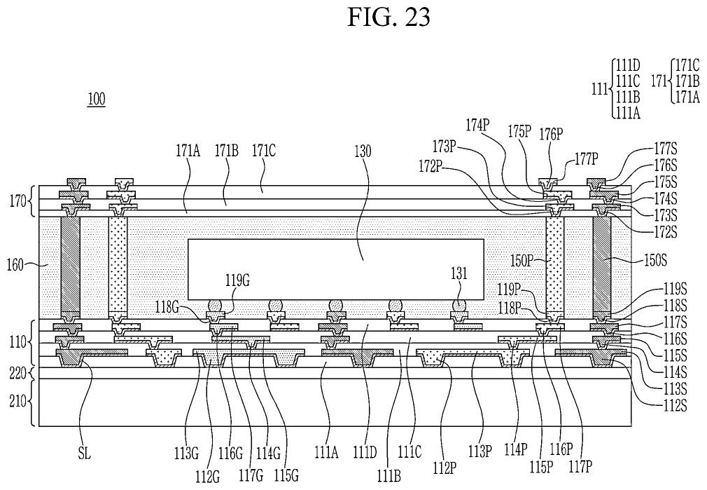

FIG. 23 illustrates a cross-sectional view of a step of forming the back side redistribution layer structure 170 on the first molding material 160.

The contents described and illustrated in the steps of forming the above-described front side redistribution layer structure 110 may be equally applied to the steps of forming the back side redistribution layer structure 170, except that the back side redistribution layer structure 170 is formed on the first molding material 160 and does not include the UBM structure 140.

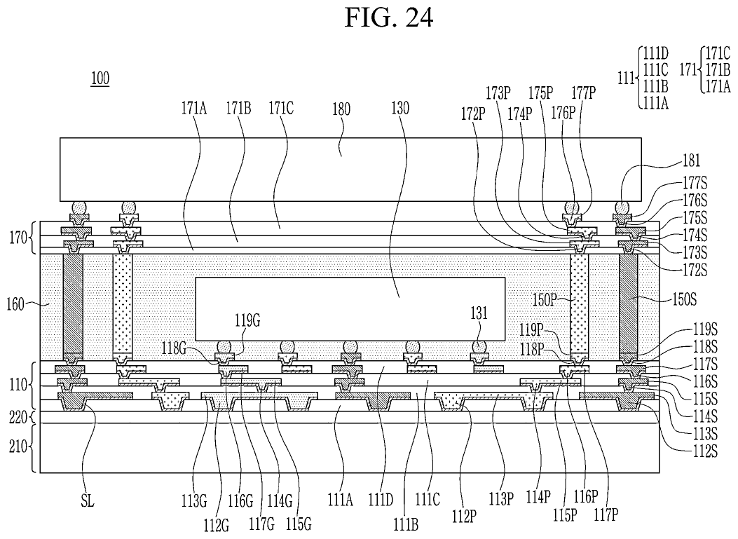

FIG. 24 illustrates a cross-sectional view of a step of mounting the second semiconductor die 180 on the back side redistribution layer structure 170.

Referring to FIG. 24, the second semiconductor die 180 may be mounted on the back side redistribution layer structure 170. The connection members 181 of the second semiconductor die 180 may be bonded to the second bonding pads 177 of the back side redistribution layer structure 170 so that the second semiconductor die 180 and the back side redistribution layer structure 170 may be electrically connected.

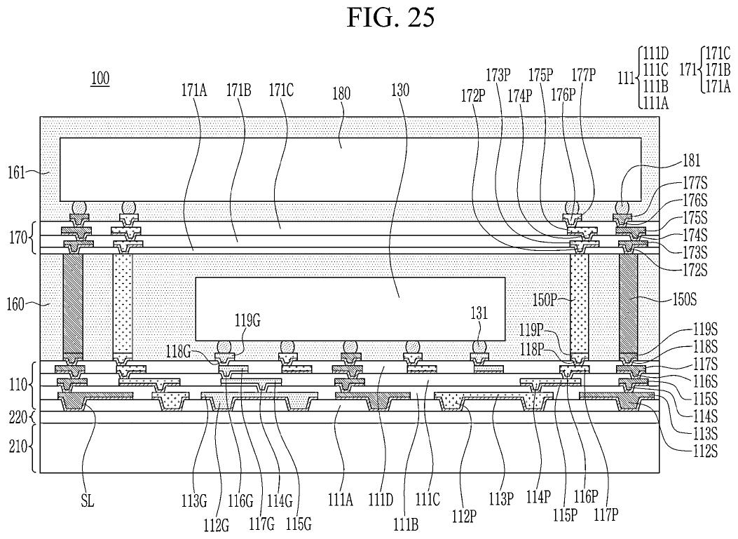

FIG. 25 illustrates a cross-sectional view of a step of molding the second semiconductor die 180 on the back side redistribution layer structure 170.

Referring to FIG. 25, the second semiconductor die 180 may be molded on the back side redistribution layer structure 170 by the second molding material 161. In the embodiment, the process of molding with the second molding material 161 may include a compression molding or transfer molding process. In the embodiment, the second molding material 161 may include an epoxy molding compound (EMC).

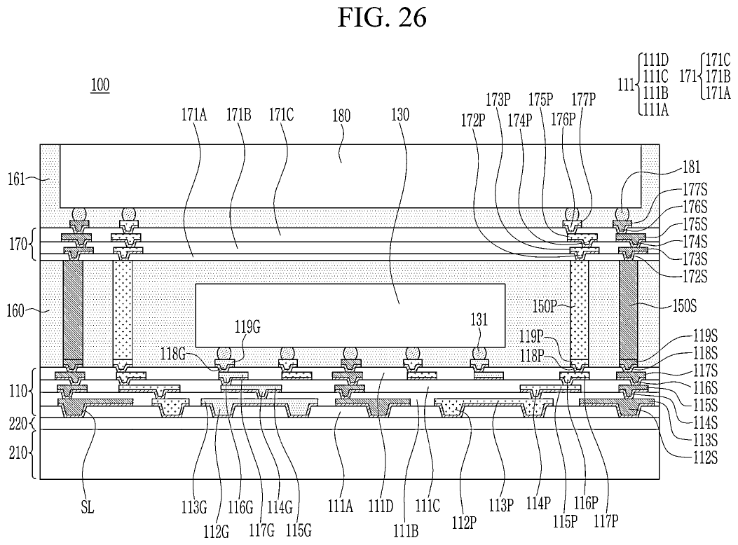

FIG. 26 illustrates a cross-sectional view of a step of performing a chemical mechanical polishing (CMP) process on the second molding material 161.

Referring to FIG. 26, the upper surface of the second molding material 161 may be planarized by performing a chemical mechanical polishing (CMP) process so as to level the upper surface of the second molding material 161. After performing the chemical mechanical polishing (CMP) process, an upper surface of the second semiconductor die 180 may be exposed.

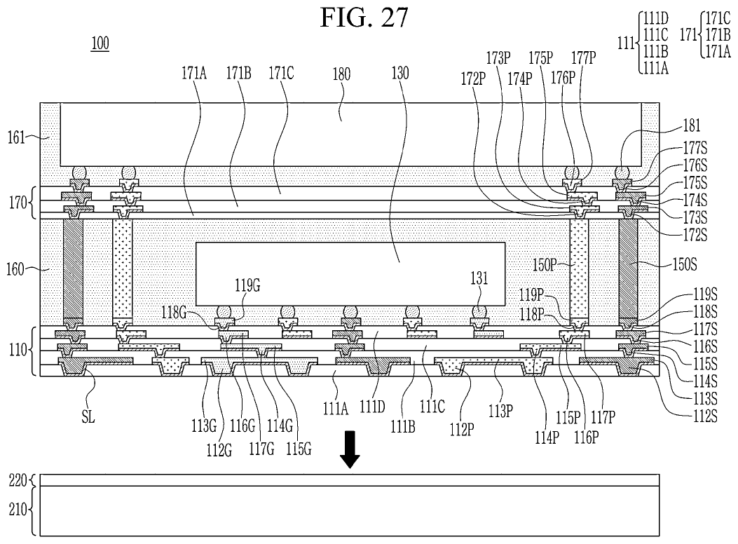

FIG. 27 illustrates a cross-sectional view of a step of removing the carrier 210 from the front side redistribution layer structure 110.

Referring to FIG. 27, the carrier 210 including the release layer 220 may be removed from the lower surface of the front side redistribution layer structure 110.

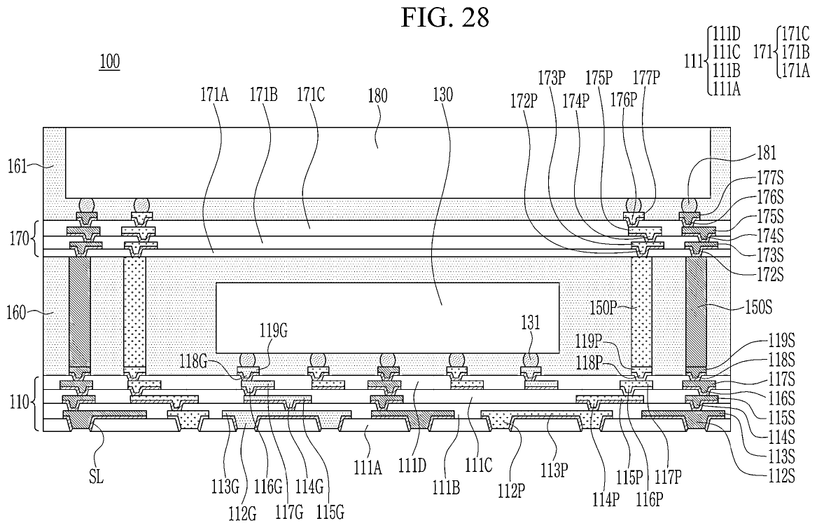

FIG. 28 illustrates a cross-sectional view of a step of etching the seed metal layer SL on the lower surface of the front side redistribution layer structure 110.

Referring to FIG. 28, the lower surface of the UBM via 112 may be exposed by etching the seed metal layer SL on the lower surface of the front side redistribution layer structure 110.

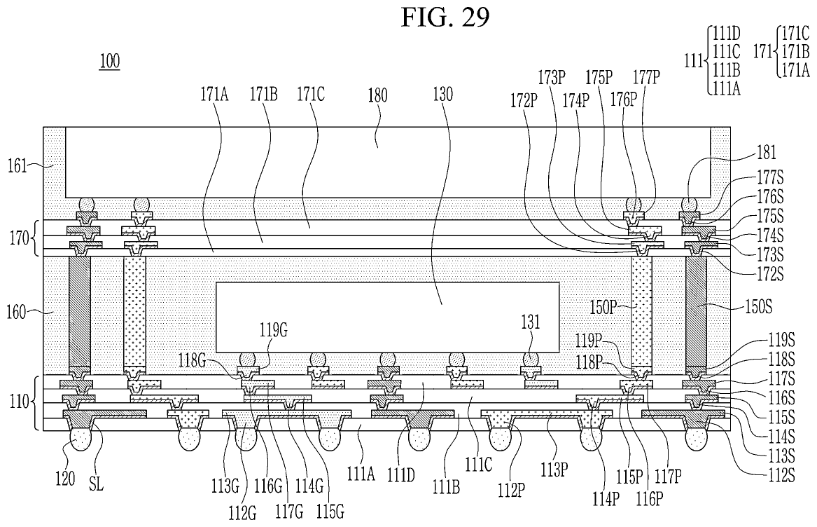

FIG. 29 illustrates a cross-sectional view of a step of forming the external connection member 120 on the lower surface of the UBM via 112.

Referring to FIG. 29, the external connection members 120 may be formed on the lower surface of the UBM via 112.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A semiconductor package comprising:
a first redistribution layer structure including a plurality of redistribution vias and a plurality of under bump metallization (UBM) structures; and
a first semiconductor die on the first redistribution layer structure,
wherein each of the plurality of UBM structures includes:
a UBM via; and
a UBM wire line extending in a horizontal direction on the UBM via and electrically connecting one of the plurality of redistribution vias and the UBM via in the horizontal direction.

2. The semiconductor package of claim 1,
wherein the plurality of UBM structures include a plurality of signal UBM structures, and
wherein UBM vias of the plurality of signal UBM structures are signal UBM vias, and UBM wire lines of the plurality of signal UBM structures are signal UBM wire lines.

3. The semiconductor package of claim 2, wherein each of the plurality of signal UBM structures includes:
one signal UBM via; and
one signal UBM wire line corresponding to the one signal UBM via.

4. The semiconductor package of claim 2, wherein the signal UBM wire line has an elongated shape.

5. The semiconductor package of claim 1,
wherein the plurality of UBM structures include a plurality of ground UBM structures, and
wherein UBM vias of the plurality of ground UBM structures are ground UBM vias, and UBM wire lines of the plurality of ground UBM structures are ground UBM wire lines.

6. The semiconductor package of claim 5, wherein each of the plurality of ground UBM structures includes:
one or more ground UBM vias; and
one ground UBM wire line corresponding to the one or more ground UBM vias.

7. The semiconductor package of claim 6,
wherein the one or more ground UBM vias is a plurality of ground UBM vias, and
wherein the one ground UBM wire line merges the plurality of ground UBM vias.

8. The semiconductor package of claim 1,
wherein the plurality of UBM structures include a plurality of power UBM structures, and
wherein UBM vias of the plurality of power UBM structures are power UBM vias, and UBM wire lines of the plurality of power UBM structures are power UBM wire lines.

9. The semiconductor package of claim 1, wherein each UBM structure has a T-type shape by combining a lower UBM via that vertically extends and an upper UBM wire line that horizontally extends.

10. The semiconductor package of claim 1,
wherein the UBM wire line includes a first portion extending in one direction and in a horizontal direction, and a second portion extending in the other direction opposite to the one direction and in the horizontal direction, based on the UBM via, and
wherein a length of the first portion in the horizontal direction and a length of the second portion in the horizontal direction are different.

11. A semiconductor package comprising:
a first redistribution layer structure including a plurality of under bump metallization (UBM) structures, a plurality of redistribution vias, a plurality of redistribution lines on the plurality of UBM structures, and a dielectric layer, wherein the dielectric layer surrounds the plurality of UBM structures, the plurality of redistribution vias, and the plurality of redistribution lines;
a plurality of connection members on a lower surface of the first redistribution layer structure;
a first semiconductor die on the first redistribution layer structure;
a plurality of conductive posts on the first redistribution layer structure;
a molding material disposed on the first redistribution layer structure and molding the first semiconductor die and the plurality of conductive posts;
a second redistribution layer structure on the molding material; and
a second semiconductor die on the second redistribution layer structure,
wherein each of the plurality of UBM structures includes:
a UBM via; and
a UBM wire line extending in a horizontal direction on the UBM via and electrically connecting one of the plurality of redistribution vias and the UBM via in the horizontal direction.

12. The semiconductor package of claim 11, further comprising:
a seed metal layer between a side wall of the UBM via and the dielectric layer, and between a lower surface of the UBM wire line and the dielectric layer.

13. The semiconductor package of claim 11, wherein the first semiconductor die includes a system on chip (SoC).

14. The semiconductor package of claim 11, wherein the second semiconductor die includes a memory semiconductor.

15. The semiconductor package of claim 11, wherein a ratio of a thickness of the first redistribution layer structure in a vertical direction to a thickness of the second redistribution layer structure in the vertical direction is about 7:5.

16. The semiconductor package of claim 11, wherein the thickness of the first redistribution layer structure in the vertical direction is about 30 μm to about 40 μm.

17. A method of manufacturing a semiconductor package, comprising:
forming a first redistribution layer structure including a plurality of under bump metallization (UBM) structures and a plurality of redistribution vias on a carrier, wherein each of the plurality of UBM structures includes a UBM via, and a UBM wire line extending in a horizontal direction on the UBM via and electrically connecting one of the plurality of redistribution vias and the UBM via in the horizontal direction;
mounting a first semiconductor die on the first redistribution layer structure;
forming a plurality of conductive posts on the first redistribution layer structure;
molding the first semiconductor die and the plurality of conductive posts with a molding material on the first redistribution layer structure; and
forming a second redistribution layer structure on the molding material.

18. The method of claim 17, wherein the UBM via and the UBM wire line are formed by performing a single film-formation process.

19. The method of claim 17, wherein the forming of the first redistribution layer structure including the plurality of UBM structures and the plurality of redistribution vias on the carrier includes:
film-forming a dielectric layer on the carrier;
forming a plurality of first openings in the dielectric layer to expose an upper surface of the carrier;
forming a seed metal layer on the exposed upper surface of the carrier, side walls of the plurality of first openings, and the dielectric layer;
forming a photoresist pattern on the seed metal layer on the dielectric layer, wherein the photoresist pattern includes a plurality of second openings, and a portion of an upper surface of the seed metal layer and the plurality of first openings are exposed in the plurality of second openings; and
filling the plurality of first openings and the plurality of second openings with a conductive material.

20. The method of claim 19, wherein the filling of the plurality of first openings and the plurality of second openings with the conductive material is performed by electrolytic plating.
